(19) United States
(12) Patent Application Publication
(10) Pub. No.: US 2011/0278722 A1
(43) Pub. Date: Nov. 17, 2011

(54) SEMICONDUCTOR DEVICE AND MANUFACTURING METHOD THEREOF

(75) Inventor: Keiji MIKI, Kyoto (JP)

(73) Assignee: PANASONIC CORPORATION, Osaka (JP)

(21) Appl. No.: 13/193,242

(22) Filed: Jul. 28, 2011

Related U.S. Application Data
(63) Continuation of application No. PCT/JP2009/007352, filed on Dec. 28, 2009.

(30) Foreign Application Priority Data
Jan. 30, 2009 (JP) 2009-019328

(51) Int. Cl. H01L 23/498

(52) U.S. Cl. 257/737; 257/E23.068

(57) ABSTRACT

A semiconductor device includes: an electrode pad formed in a chip region on a substrate; and a protruding portion continuously formed in a region outside the electrode pad within the chip region so as to surround a region inside the chip region. The protruding portion is higher than the electrode pad.

### CROSS-REFERENCE TO RELATED APPLICATION

This is a continuation of PCT International Application PCT/JP2009/007352 filed on Dec. 28, 2009, which claims priority to Japanese Patent Application No. 2009-019328 filed on Jan. 30, 2009. The disclosures of these applications including the specifications, the drawings, and the claims are hereby incorporated by reference in their entirety.

### BACKGROUND

Semiconductor devices are typically produced by placing a multiplicity of integrated circuits (ICs), each formed by a plurality of elements and having a predetermined function, in a matrix pattern on, e.g., a semiconductor wafer such as silicon.

A multiplicity of chip regions placed on the wafer are separated from each other by a scribe region (a scribe line) provided in a grid pattern. After forming a plurality of chip regions on a single wafer through a semiconductor manufacturing process, the wafer is divided into individual semiconductor devices through the step of grinding the wafer from its back surface to a predetermined thickness, the step of dicing the wafer along a scribe region into individual chips, and the subsequent mounting step.

However, when dicing the wafer into the individual chips, an interlayer insulating film having high water permeability and high hygroscopicity is exposed from the end faces of each chip. Thus, water, mobile ions, etc. having entered the interlayer insulating film from the end faces of the chip may spread into the chips, thereby corroding interconnects, reducing resistance of insulating films, degrading characteristics of elements, etc. Moreover, when dicing the wafer into individual chips, the chip regions around the scribe line are subjected to mechanical impact, whereby cracks or chippings can be produced in the dicing cross sections of the divided chips.

As a solution to such a problem, a ring-shaped protection wall called a “seal ring” is increasingly provided around each chip region to protect each chip region from entrance of water, mobile ions, etc. and from the mechanical impact.

FIG. 25 is a plan view of a semiconductor device having a seal ring as related art. FIG. 26 is a diagram showing a cross-sectional structure taken along line XXVI-XXVI′ in FIG. 25. FIG. 27 shows a state where a plurality of semiconductor devices, each having a seal ring, are formed on a substrate formed by a wafer.

As shown in FIGS. 25-26, a plurality of chip regions 112, each defined by a scribe region 113, are formed on a substrate 111 formed by a wafer. A stacked insulating film 170, which is formed by a plurality of interlayer insulating films 115-120, is formed on the substrate 111.

In the chip region 112, an active layer 130 configured to form an element is formed in the substrate 111. An interconnect structure 171 connecting to the active layer 130 is formed in the stacked insulating film 170. More specifically, a via 131 connecting to the active layer 130 is formed in the interlayer insulating film 115, an interconnect 132 connecting to the via 131 is formed in the interlayer insulating film 116, a via 133 connecting to the interconnect 132 is formed in the interlayer insulating film 117, an interconnect 134 connecting to the via 133 is formed in the interlayer insulating film 118, a via 135 connecting to the interconnect 134 is formed in the interlayer insulating film 119, and an interconnect connecting to the via 135 is formed in interlayer insulating film 120, thereby forming the interconnect structure 171.

A seal ring 114 is formed in a stacked structure of the plurality of interlayer insulating films 115-120 in a peripheral edge of the chip region 112. The seal ring 114 extends through the stacked structure, and continuously surrounds the chip region 112. The seal ring 114 is formed by alternatively stacking seal interconnects each formed by a mask for forming an interconnect, and seal vias each formed by a mask for forming a via. Specifically, the seal ring 114 is formed by a conductive layer 140 formed in the substrate 111, a seal via 141 formed in the interlayer insulating film 115 and connecting to the conductive layer 140, a seal interconnect 142 formed in the interlayer insulating film 116 and connecting to the seal via 141, a seal via 143 formed in the interlayer insulating film 117 and connecting to the seal interconnect 142, a seal interconnect 144 formed in the interlayer insulating film 118 and connecting to the seal via 143, a seal via 145 formed in the interlayer insulating film 119 and connecting to the seal interconnect 144, and a seal interconnect formed in the interlayer insulating film 120 and connecting to the seal via 145.

Moreover, a passivation film 121 is provided on the stacked insulating film 170 in which the interconnects (132, 134, 136), the vias (131, 133, 135), and the seal ring 104 are provided. The passivation film 121 has openings on the interconnect 136 and on the seal interconnect 146, respectively. A pad 137 connecting to the interconnect 136 and a cap layer 147 connecting to the seal interconnect 146 are formed in the openings, respectively.

Another passivation film 122 having openings over the seal ring 114 and on the pad 137, respectively, is formed over the passivation film 121. A protective film 123 having an opening on the pad 137 and the periphery thereof and on the seal ring 114 is formed in order to protect the chip region 112.

Since the structure shown in FIGS. 25-26 has a wall that protects the chip region 112 from mechanical impact in the dicing process, the possibility is reduced that cracks may spread to the chip region 112. Moreover, since the passivation film 121 has the opening on the seal ring 114, the possibility is reduced that the passivation film on the chip region 112 may be delaminated by the impact in the dicing process. Since the cap layer 147 is formed in the opening of the passivation film 121 on the seal ring 14, the possibility that water, impurities, etc. may enter the chip region 112 from the scribe region 113 in the dicing process can be reduced as compared to the case where the cap layer 147 is not provided.

However, the following is known regarding semiconductor devices having such a structure.

Typically, after the chip regions 112 having the structure as shown in FIGS. 25-26 is formed on the substrate 111 formed by the wafer by a semiconductor manufacturing process, the wafer is ground from its rear surface to a predetermined thickness, and is then diced into individual chips along the scribe region 113.

When grinding the rear surface of the wafer, a protective tape is bonded to the front surface, namely the patterning surface, of the wafer, and the wafer is ground from its rear surface by pressing a grinding stone, rotating at a high speed, against the rear surface of the wafer. During the grinding process, water is sprayed in order to wash away cutting debris produced, and to reduce frictional heat that is generated by the grinding process.

As shown in FIG. 27, the scribe region 113 is formed to extend to the outermost periphery of the wafer. The protective film 123 is formed on the chip region 112. The protective film 123 is provided in order to protect the chip region 112 from scratches and contamination, and has a certain thickness (around 5 μm). Thus, there is a difference in height between the scribe region 113 and the protective film 123. When the protective tape is bonded to grind the rear surface of the wafer, this difference in height cannot be eliminated, whereby a gap can be formed between the protective tape and the scribe region.

When grinding the rear surface of the wafer, cutting water including cutting debris may enter the gap in the outer periphery of the wafer, and may spread inward on the wafer along the scribe line, thereby contaminating the front surface of each chip.

As a solution, Japanese Patent Publication No. 2001-274129 discloses a technique in which a scribe line extending in a grid pattern is divided by a bank that is formed near each intersection of the scribe line when patterning a protective film (a polyimide film) for protecting chip regions. According to this method, since the banks are provided on the scribe line, cutting water including cutting debris is not allowed to spread beyond the banks even if the cutting water enters the gaps between the scribe line and the protective tapes. This can reduce the possibility of contamination of electrode pads in the chip regions located beyond the banks, and contamination of the front surfaces of chips.

In recent years, semiconductor devices have become increasingly thinner for applications to mobile apparatuses, and thus there has been a growing demand for chips having a smaller thickness. For example, chips having a thickness of about 100 μm or less have been increasingly used in applications.

However, in conventional manufacturing methods, that is, in manufacturing methods in which grinding of the rear surface of a wafer and dicing are performed after forming a plurality of chip regions on the single wafer, fractures and cracks may be produced during transportation within an apparatus due to warping of the wafer which is caused after the process of grinding the rear surface of the wafer. Moreover, the ground wafer sometimes fractures due to wrong handling. Furthermore, dicing the wafer after grinding the wafer to a thickness of less than 100 μm sometimes causes cracks in chips due to impact in the dicing process. Such fractures and cracks contribute to reduction in manufacturing yield and quality.

As a solution, Japanese Patent Publication No. H05-335411 discloses a technique in which the step of forming grooves is first performed to form grooves in the front surface of a wafer along a scribe line, and then the step of grinding the rear surface of the wafer is performed so that these grooves extend to the rear surface, thereby dividing the wafer into individual chips. This method allows the wafer to be handled without causing any fracture in the state of the wafer since the wafer has a sufficient thickness, and also can reduce generation of cracks in the step of forming the grooves since the wafer is cut from its front surface to an intermediate depth in the thickness direction.

This method is called a “dicing before grinding (DBG) method,” and is a manufacturing method that is especially effective when a wafer has a large diameter, and when a finished thickness after grinding the rear surface of the wafer is small.

### SUMMARY

However, the above techniques have the following problems.

In the technique of Japanese Patent Publication No. 2001-274129, entrance of the cutting water can be reduced by providing the banks on the scribe line. However, in the subsequent dicing step, the protective film that is present on the scribe line can cause clogging of a dicing blade. This may increase chippings, thereby reducing quality and manufacturing yield.

In the technique of Japanese Patent Publication No. H05-335441, even if a protective film is formed at the intersections (near the corners of each chip region) of the scribe line, this protective film cannot function as a bank. That is, since the grooves have already been formed in the scribe line when grinding the rear surface of the wafer, cutting water enters the chip regions through the grooves, thereby contaminating the chip regions.

It has been desired to solve these problems.

In view of the above problems, a high yield, inexpensive thin semiconductor device and a manufacturing method thereof will be described below, which reliably reduce the possibility of contamination of chips due to entrance of cutting water from a scribe line when grinding the rear surface of the wafer, and in which the front surfaces of the chips are not soiled even when a DBG method is used.

A semiconductor device according to the present disclosure includes: an electrode pad formed in a chip region on a substrate; and a protruding portion continuously formed on a region outside the electrode pad within the chip region so as to surround a region inside the chip region, wherein the protruding portion is higher than the electrode pad.

The chip region may include an element formed in the substrate, an interlayer insulating film formed on the substrate, and an interconnect structure formed in the interlayer insulating film and connected to the element, and the electrode pad may be connected to the element via the interconnect structure.

It is preferable that the semiconductor device further include a seal ring continuously formed in the interlayer insulating film so as to surround the element and the interconnect structure, and that the protruding portion be formed at least over the seal ring.

Typically, semiconductor devices are respectively formed in the chip regions of the wafer, and then the wafer is divided into the individual semiconductor devices by grinding the rear surface of the wafer and performing dicing along a scribe region. When grinding the rear surface of the wafer, a protective tape is closely bonded to the front surface of the wafer by using a bonding roller. However, since the bonding roller presses the entire surface of the wafer, the protective tape may not completely adhere to the front surface of the wafer if there is a difference in height between the chip region and the scribe region.

However, the semiconductor device of the present disclosure has the protruding portion that is continuously formed on the region outside the electrode pad that is formed in the chip region on the substrate, and the protruding portion is higher than the electrode pad. Thus, when bonding the protective tape to grind the rear surface of the wafer, the bonding roller presses the protruding portion located outside the electrode pad, allowing the protective tape to closely adhere to the protruding portion. Thus, there is a gap between the protective tape and the scribe region, whereby the possibility that cutting water may enter a region inside the protruding portion (a region inside each chip region) can be reduced even if the cutting water enters the gap. This can reduce the possibility of contamination of the front surfaces of the chips with the cutting water.

Moreover, in the case where the seal ring is provided to protect the chip region from entrance of water, mobile ions, etc. and from mechanical impact, and the protruding portion is formed over the seal ring, the protruding portion can be formed by using a region over the seal ring, without increasing the chip size. This is advantageous in reducing manufacturing cost.

It is preferable that a cap layer be provided on the seal ring, and that the protruding portion be formed at least over the seal ring with the cap layer interposed therebetween.

This relatively increases the height of the protruding portion with respect to the electrode pad. Thus, when bonding the protective tape with the bonding roller to grind the rear surface of the wafer, the protective tape is allowed to more firmly adhere to the protruding portion, thereby enhancing the effect of reducing contamination of the chip regions with the cutting water.

The semiconductor device may further include a protective film made of an organic film and formed on the interlayer insulating film in a region inside the protruding portion. It is also preferable that the protruding portion have a height equal to or greater than that of the protective film.

Thus, even in the case where the protective film is provided to protect the chip region, the protruding portion surrounding the chip region is the highest in a region near the boundary between the scribe region and the chip region. This allows the protective tape to more reliably closely adhere to the protruding portion, thereby more reliably reducing the possibility of contamination of the chip regions in the manufacturing process.

It is preferable that at least an upper surface of the protruding portion be a rough surface portion.

This can further increase the degree of adhesion between the protective tape and the protruding portion, thereby more reliably reducing contamination of the chip regions with the cutting water.

The protruding portion may be made of an organic film. The organic film may be formed by applying a liquid resin to an entire surface over the substrate and patterning the liquid resin.

Thus, the protruding portion can be formed by using a lithography technique, whereby cost for the step of forming the protruding portion can be reduced. Moreover, in the case where the protective film made of the organic film is provided, the protective film and the protruding portion can be formed simultaneously, whereby manufacturing cost can further be reduced.

The protruding portion may be a protruding portion made of a metal and connected to the seal ring.

In this structure, the interlayer insulating film, the protective film, etc. are divided between the chip region and the scribe region by the seal ring and the protruding portion. Thus, the possibility can be reduced that water and impurities may enter the chip regions from dicing end faces.

It is preferable that the protruding portion be a protruding portion made of a metal and connected to the seal ring, and that a protruding electrode be formed on the electrode pad.

Thus, the protruding portion can be formed simultaneously with forming the protruding electrode on the electrode pad, whereby the semiconductor device can be manufactured without increasing the number of steps.

It is preferable that the protruding portion made of the metal be higher than the protruding electrode.

This allows the protective tape to more reliably closely adhere to the protruding portion made of the metal, thereby more reliably reducing the possibility of contamination of the chip regions in the manufacturing process.

It is preferable that the protruding portion made of the metal contain one of Ni, Au, Cu, Sn, and Al as a main component.

This allows the protruding portion made of the metal to be formed by a manufacturing method, a manufacturing apparatus, etc. of a conventional semiconductor device.

A manufacturing method of a semiconductor device according to the present disclosure is a manufacturing method of a semiconductor device in which semiconductor devices respectively formed in a plurality of chip regions are separated from each other along a scribe region, including the steps of: (a) forming an element in a substrate in each of the plurality of chip regions; (b) forming an interlayer insulating film on the substrate, and forming in the interlayer insulating film an interconnect structure including an interconnect layer and a via that are electrically connected to the element; (c) forming on the interlayer insulating film a passivation film having an opening over at least a part of the interconnect structure; (d) forming in the opening an electrode pad connected to the interconnect structure; and (e) forming, over a region located outside the electrode pad within the chip region, a protruding portion continuously surrounding the interconnect structure and the element and higher than the electrode pad.

According to such a manufacturing method of the semiconductor device, the protruding portion higher than the electrode pad can be provided over the region located outside the electrode pad within the chip region. This can reduce the possibility that cutting water may enter the chip regions from the scribe region when grinding the rear surface of the substrate, thereby reducing contamination of the chip regions with the cutting water.

It is preferable that a conductive layer surrounding the element be further formed in the step (a), that a seal ring, which includes a seal interconnect and a seal via that are electrically connected to the conductive layer and which continuously surrounds the interconnect structure and the element, be further formed in the interlayer insulating film in the step (b), and that the protruding portion be formed at least over the seal ring in the step (e).

Another opening may further be formed over the seal ring in the passivation film in the step (c), a cap layer connected to the seal ring may further be formed in the another opening in the step (d), and the protruding portion may be formed at least over the cap layer in the step (e).

This allows the protruding portion to be provided over the seal ring that is provided as a protection against entrance of water and mobile ions, against mechanical impact, etc, whereby contamination of the chip regions with the cutting water can be reduced without increasing the chip size.

After the step (d), a protective film made of an organic film and having an opening so as to expose at least the electrode pad may further be formed on the passivation film.

Note that it is preferable that the protruding portion have a height equal to or greater than that of the protective film.

Thus, the protruding portion is higher than the other portions (the protective film, etc.), thereby increasing adhesion between the protruding portion and a protective tape, and thus enhancing the effect of reducing entrance of the cutting water.

It is preferable that the manufacturing method further include after the step (e) the step of roughening at least an upper surface of the protruding portion.

This can increase the degree of adhesion between the protective tape and the protruding portion, thereby more reliably reducing contamination of the chip regions with the cutting water.

The protruding portion made of an organic film may be formed in the step (e).

It is preferable that in step (e), a protective film made of an organic film and having an opening so as to expose at least the electrode pad be formed, and that the protruding portion be formed at least on the cap layer.

Thus, the protruding portion made of the organic film can be formed over the seal ring simultaneously with forming the protective film made of the organic film on the chip region. That is, the semiconductor device having the protruding portion can be manufactured without increasing the number of manufacturing steps. Moreover, providing the protruding portion on the cap layer makes the protruding portion higher than the organic film (the protective film) in the remaining region. Thus, when bonding the protective tape to the front surface of a wafer to grind the rear surface of the wafer, the protruding portion is higher than the other portions, thereby allowing the protective tape to more firmly adhere to the protruding portion, and enhancing the effect of reducing contamination of the chip regions with the cutting water.

It is preferable that the protruding portion made of a metal be formed in the step (e).

Thus, the semiconductor device is obtained which has the protruding portion connected to the seal ring and made of the metal. Moreover, the passivation film, the interlayer insulating film, etc. are partially divided over the seal ring. This can reduce the possibility that water and impurities may enter the chip regions from the dicing end faces.

It is preferable that another opening be formed over the seal ring in the passivation film in the step (c), that a cap layer connected to the seal ring be further formed in the another opening in the step (d), that the manufacturing method further include between the steps (d) and (e) the step of forming an organic film on the passivation film, that the organic film have an opening larger than the electrode pad so as to expose at least the electrode pad, and have an opening smaller than the cap layer on the cap layer, and that the protruding portion made of the metal be formed on the cap layer, and a protruding electrode be formed on the electrode pad in the step (e).

Thus, the protruding portion can be simultaneously formed in the step of providing the protruding electrode, thereby reducing the possibility of an increase in the number of steps. Moreover, the another opening and the cap layer allow the passivation film, the interlayer insulating film, etc. to be partially divided over the seal ring, thereby reducing the possibility that water, etc. may enter the chip regions from the dicing end faces.

Moreover, the height of the protruding portion can be increased by forming the organic film having the opening smaller than the cap layer on the cap layer, and forming the protruding portion in this opening. This enhances the effect of reducing entrance of the cutting water. Moreover, the possibility of an increase in the number of steps can be reduced by simultaneously forming this organic film in the step of forming the organic film as the protective film on the chip region.

Any of the above manufacturing methods of the semiconductor device may further include the steps of: (f) after the step (e), bonding a protective tape to a main surface side of the substrate, grinding the substrate from another surface of the substrate to a predetermined thickness; and (g) after the step (f), dicing the substrate into the individual chip regions along the scribe region.

Any of the above manufacturing method of the semiconductor device may further include the steps of: (h) after the step (e), forming along the scribe region in the substrate a groove having a predetermined depth from a main surface side of the substrate; and (i) after the step (h), bonding a protective tape to the main surface side of the substrate, and grinding the substrate from another surface thereof so as to reach the groove, thereby dividing the substrate into the individual chip regions.

Thus, regardless of whether a method in which dicing is performed after grinding the rear surface of the substrate or a DBG method in which the groove is formed before grinding the rear surface of the substrate is used, the possibility is reduced that the cutting water may enter the chip regions when grinding the rear surface of the substrate, whereby contamination of the chip regions can be reduced. The term “main surface” represents a surface of the substrate located on the side where the element is formed. It can also be said that the “main surface” represents a surface located on the side where the protruding portion is formed.

According to the technique described above, since the protruding portion is provided in the peripheral edge of each chip region so as to surround the chip region, the protective tape is allowed to closely adhere to the protruding portion when bonding the protective tape to grind the rear surface of the substrate. Thus, even if cutting water enters the scribe region in the outer periphery of the wafer in the grinding process, the possibility can be reduced that the cutting water may enter the chip regions. Accordingly, the possibility of contamination of the chip regions can be reduced. This effect can be produced not only when dicing is performed after grinding the rear surface of the substrate, but also when a DBG method is used because the protruding portion is provided in each chip region.

### BRIEF DESCRIPTION OF THE DRAWINGS

FIG. 1 is a plan view showing a part of a wafer on which an example semiconductor device of a first embodiment is provided.

FIG. 2 is a cross-sectional view showing a cross-sectional structure taken along line II-IF in FIG. 1.

FIGS. 3A-3E are cross-sectional views illustrating a manufacturing method of the example semiconductor device of the first embodiment.

FIGS. 4A-4D are cross-sectional views illustrating the manufacturing method of the example semiconductor device of the first embodiment after FIG. 3E.

FIGS. 5A-5D are cross-sectional views illustrating the manufacturing method of the example semiconductor device of the first embodiment after FIG. 4D.

FIGS. 6A-6C are cross-sectional views illustrating the manufacturing method of the example semiconductor device of the first embodiment after FIG. 5D.

FIGS. 7A-7B are cross-sectional views illustrating the manufacturing method of the example semiconductor device of the first embodiment after FIG. 6C.

FIGS. 8A-8C are cross-sectional views illustrating grinding of the rear surface of the wafer and dicing in the manufacturing method of the example semiconductor device of the first embodiment.

FIG. 9 is a plan view showing a part of a wafer on which an example semiconductor device of a second embodiment is provided.

FIG. 10 is a cross-sectional view showing a cross-sectional structure taken along line X-X′ in FIG. 9.

FIGS. 11A-11B are cross-sectional views illustrating a manufacturing method of the example semiconductor device of the second embodiment.

FIG. 12 is a plan view showing a part of a wafer on which an example semiconductor device of a third embodiment is provided.

FIG. 13 is a cross-sectional view showing a cross-sectional structure taken along line XIII-XIII′ in FIG. 12.

FIGS. 14A-14D are cross-sectional views illustrating a manufacturing method of the example semiconductor device of the third embodiment.

FIG. 15 is a plan view showing a part of a wafer on which an example semiconductor device of a fourth embodiment is provided.

FIG. 16 is a cross-sectional view showing a cross-sectional structure taken along line XVI-XVI′ in FIG. 15.

FIGS. 17A-17B are cross-sectional views illustrating a manufacturing method of the example semiconductor device of the fourth embodiment.

FIGS. 18A-18C are cross-sectional views illustrating grinding of the rear surface of the wafer and dicing in the manufacturing method of the example semiconductor device of the fourth embodiment.

FIG. 19 is a plan view showing a part of a wafer on which an example semiconductor device of a fifth embodiment is provided.

FIG. 20 is a cross-sectional view showing a cross-sectional structure taken along line XX-XX′ in FIG. 19.

FIG. 21A-21D are cross-sectional views illustrating a manufacturing method of the example semiconductor device according to the fifth embodiment.

FIG. 22 is a plan view showing a part of a wafer on which an example semiconductor device of a sixth embodiment is provided.

FIG. 23 is a cross-sectional view showing a cross-sectional structure taken along line XXIII-XXIII′ in FIG. 22.

FIG. 24A-24B are cross-sectional views illustrating a manufacturing method of the example semiconductor device of the sixth embodiment.

FIG. 25 is a plan view showing a part of a wafer on which a semiconductor device as related art is provided.

FIG. 26 is a cross-sectional view showing a cross-sectional structure taken along line XXVI-XXVI′ in FIG. 25.

FIG. 27 is a partial plan view showing an outer peripheral portion of a wafer on which semiconductor devices are provided.

### DETAILED DESCRIPTION

Embodiments of the present disclosure will be described below with reference to the accompanying drawings. Note that the material and shape of each component, the method of forming each component, etc. are shown by way of example only, and are not limited to the description below. Even in different embodiments, common configurations are denoted by the same reference characters in the figures, and detailed description thereof may be omitted.

### First Embodiment

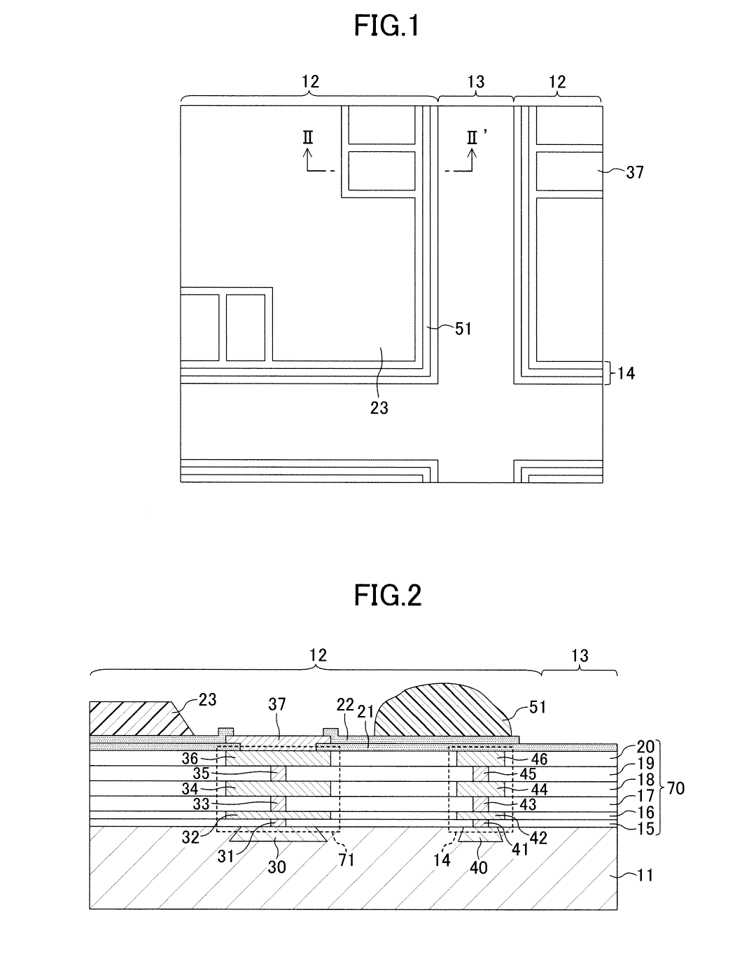

A first embodiment will be described below. FIG. 1 is a plan view showing an example semiconductor device of the present embodiment. FIG. 2 is a diagram showing a cross-sectional structure taken along line II-II′ in FIG. 1. These figures show a state where a plurality of chip regions 12 and a scribe region 13 configured to separate the chip regions 12 from each other by dicing are formed in a wafer.

The semiconductor device is formed by using a substrate 11. A stacked insulating film 70 is formed on the substrate 11 by sequentially stacking a plurality of interlayer insulating films 15, 16, 17, 18, 19, and 20 in this order from the bottom.

In the chip region 12, an active layer 30 that forms an element (the element is not shown) is formed in an upper part of the substrate 11, and an interconnect structure 71 connected to the active layer 30 is formed in the stacked insulating film 70. The interconnect structure 71 includes a via 31 formed in the interlayer insulating film 15 and connecting to the active layer 30, an interconnect 32 formed in the interlayer insulating film 16 and connecting to the via 31, a via 33 formed in the interlayer insulating film 17 and connecting to the interconnect 32, an interconnect 34 formed in the interlayer insulating film 18 and connecting to the via 33, a via 35 formed in the interlayer insulating film 19 and connecting to the interconnect 34, and an interconnect 36 formed in the interlayer insulating film 20 and connecting to the via 35.

In the peripheral edge of the chip region 12, a conductive layer 40 is formed in the upper part of the substrate 11, and a seal ring 14 is formed to extend through the stacked insulating film 70. The conductive layer 40 and the seal ring 14 are formed so as to continuously surround the active layer 30, the interconnect structure 71, etc. The seal ring 14 has a structure in which seal interconnects each formed by using a mask for forming an interconnect, and seal vias each formed by using a mask for forming a via are alternately stacked. Specifically, the seal ring 14 includes a seal via 41 formed in the interlayer insulating film 15 and connected to the conductive layer 40, a seal interconnect 42 formed in the interlayer insulating film 16 and connected to the seal via 41, a seal via 43 formed in the interlayer insulating film 17 and connected to the seal interconnect 42, a seal interconnect 44 formed in the interlayer insulating film 18 and connected to the seal via 43, a seal via 45 formed in the interlayer insulating film 19 and connected to the seal interconnect 44, and a seal interconnect 46 formed in the interlayer insulating film 20 and connected to the seal via 45.

Moreover, a passivation film 21 is provided so as to cover the stacked insulating film 70 in which the interconnect structure 71 and the seal ring 14 are provided. The passivation film 21 has an opening on the interconnect structure 71 (the interconnect 36). A pad electrode 37 connecting to the interconnect 36 is formed in the opening.

Another passivation film 22 is formed on the passivation film 21 other than a region on the pad electrode 37. In order to protect the chip region 12, a protective film 23 is formed on the passivation film 22 so as to have an opening on the pad electrode 37, the seal ring 14, etc.

A protruding portion 51 made of an organic film is formed in a part of the chip region 12, which is located outside the pad electrodes 37 and includes a region over the seal ring 14, so as to continuously surround the chip region 12. The protruding portion 51 is higher than the pad electrode 37.

The structure shown in FIGS. 1-2 can reduce the possibility of contamination of the front surface of the chip region 12 with cutting water when grinding the rear surface of the wafer. That is, by bonding a protective tape to the front surface of the wafer, the protective tape is allowed to closely adhere to the protruding portion 51 that extends along the entire peripheral edge of the chip region 12. Thus, even if there is a gap between the protective tape and the scribe region 13, and the cutting water enters the gap when grinding the rear surface of the wafer, the possibility is reduced that that the cutting water may enter the chip region 12. Thus, contamination of the chip region 12 is reduced.

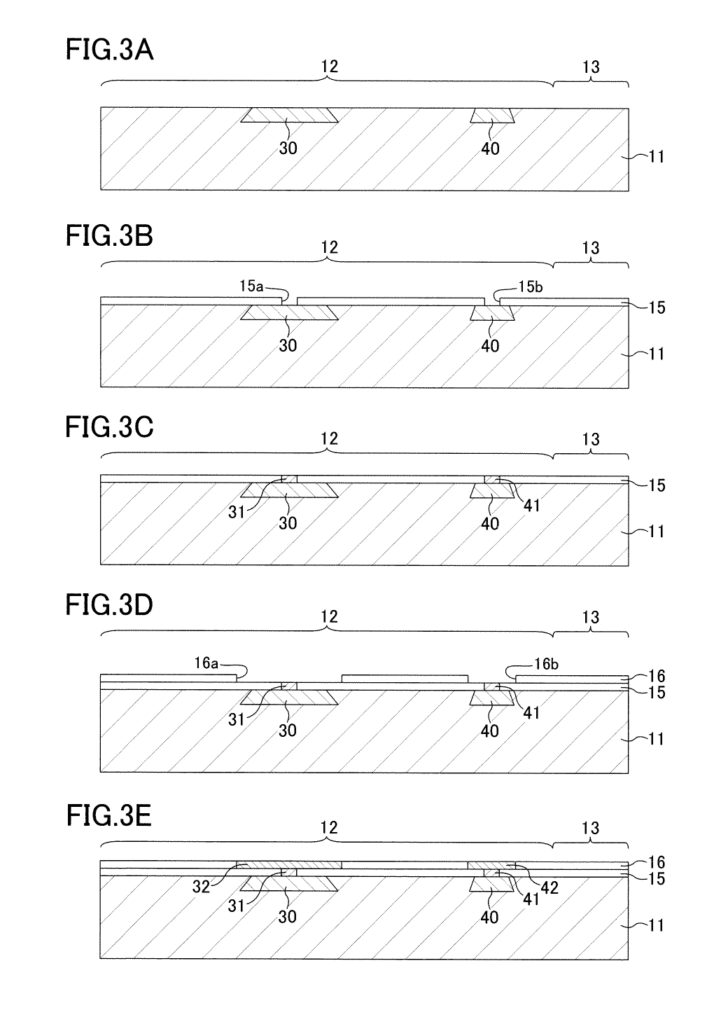

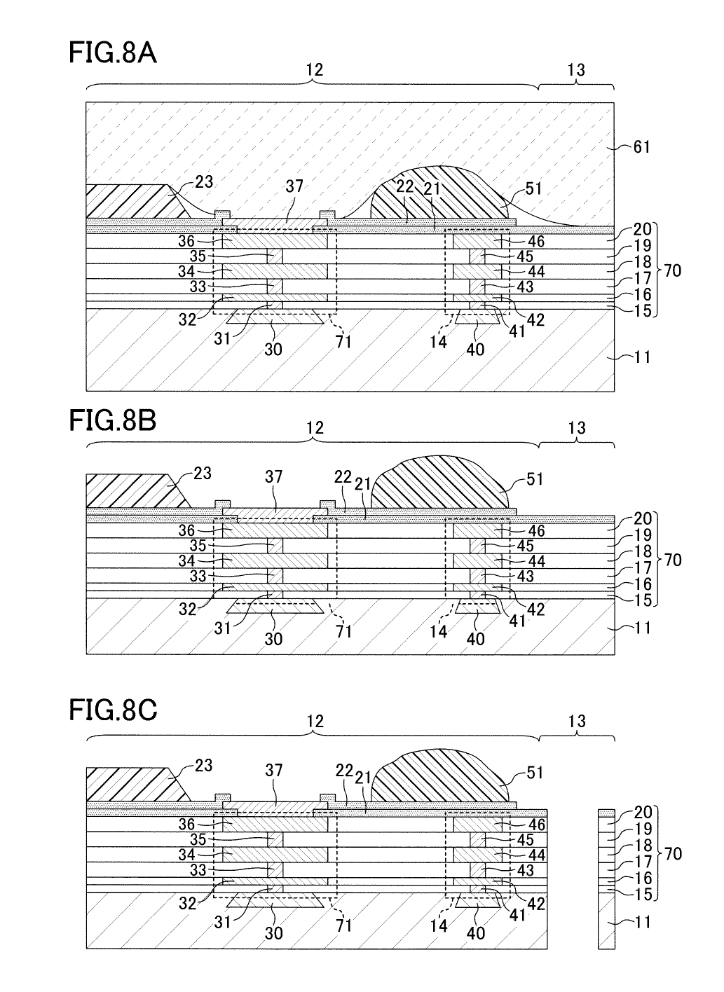

A manufacturing method for forming the structure shown in FIGS. 1-2 and a method for dicing the wafer into the individual chip regions 12 as semiconductor devices will be described below. FIGS. 3A-3E, 4A-4D, 5A-5D, 6A-6C, and 7A-7B are diagrams sequentially illustrating a process of forming the structure having a cross section taken along line II-II′ in FIG. 1. FIGS. 8A-8C are diagrams illustrating grinding of the rear surface of the wafer and dicing.

First, as shown in FIG. 3A, an active layer 30 that forms an element such as a transistor is formed in a chip region 12 of a wafer (a substrate 11), and a conductive layer 40 configured similarly to the active layer 30 is formed in a region located closer to the peripheral edge of the wafer than the active layer 30.

Next, as shown in FIG. 3B, an interlayer insulating film 15 is deposited over the substrate 11. In the interlayer insulating film 15, a via hole 15a configured to form a via 31 is formed on the active layer 30, and a groove-like recess 15b configured to form a seal via 41 is formed on the conductive layer 40. A lithography method and a dry etching method can be used in this step.

The seal via is a member that forms a seal ring, and the seal via is formed by embedding a conductive material in the groove-like recess. That is, the seal via has a linear structure having about the same width as the via. Since the seal ring is structured to continuously surround an element, etc. in a chip region, the seal via also has a continuous annular shape.

Note that in the illustrated example, the groove-like recess 15b is simultaneously formed when forming the via hole 15a in the interlayer insulating film 15. However, the present disclosure is not limited to this, and the via hole 15a and the groove-like recess 15b may be formed separately.

Then, the step shown in FIG. 3C is performed. First, the via hole 15a and the groove-like recess 15b provided in the interlayer insulating film 15 are filled with a conductive film made of tungsten (W) by using, e.g., a chemical vapor deposition (CVD) method. Then, the excess conductive film formed outside the via hole 15a and the groove-like recess 15b is removed by using, e.g., a chemical mechanical polishing (CMP) method, thereby forming the via 31 connecting to the active layer 30, and the seal via 41 connecting to the conductive layer 40.

Then, the step shown in FIG. 3D is performed. First, an interlayer insulating film 16 is deposited on the interlayer insulating film 15. In the interlayer insulating film 16, an interconnect groove 16a configured to form an interconnect 32 is formed on the via 31, and a seal interconnect groove 16b configured to form a seal interconnect 42 is formed on the seal via 41. A lithography method and a dry etching method can be used in this step.

Thereafter, the step shown in FIG. 3E is performed. First, the interconnect groove 16a and the seal interconnect groove 16b provided in the interlayer insulating film 16 are filled with a conductive film made of copper (Cu), by using, e.g., an electroplating method. Then, the excess conductive film formed outside the interconnect groove 16a and the seal interconnect groove 16b is removed by using, e.g., a CMP method, thereby forming the interconnect 32 connecting the via 31, and the seal interconnect 42 connecting to the seal via 41.

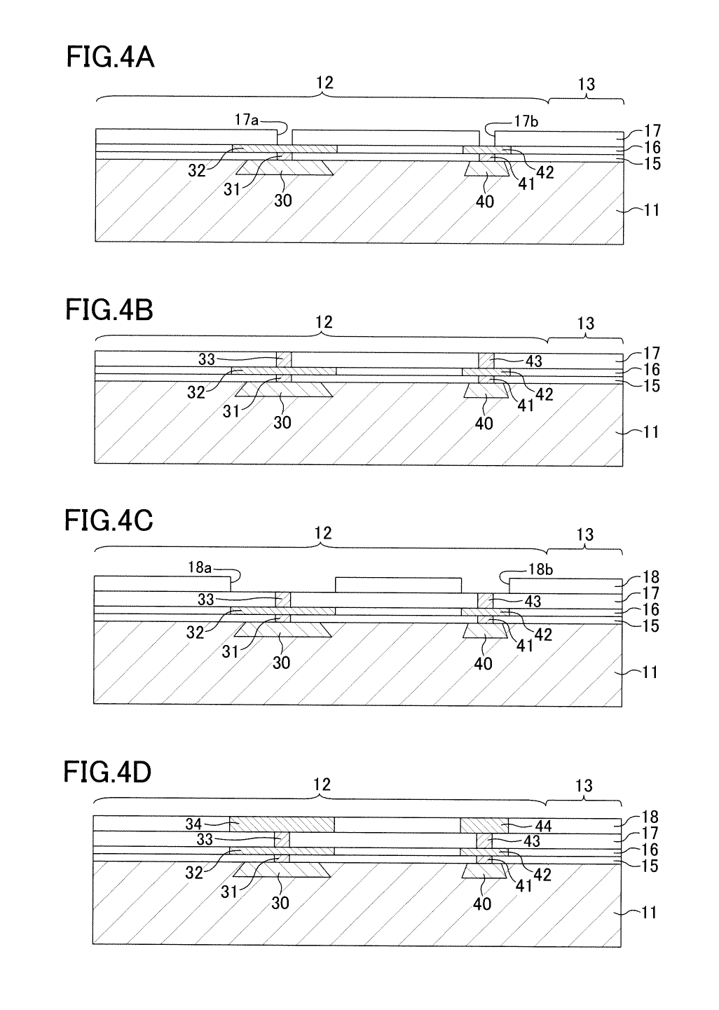

Then, the step shown in FIG. 4A is performed. First, an interlayer insulating film 17 is formed over the interlayer insulating film 16. Then, in the interlayer insulating film 17, a via hole 17a configured to form a via 33 is formed on the interconnect 32, and a groove-like recess 17b configured to form a seal via 43 is formed on the seal interconnect 42. The via hole 17a and the groove-like recess 17b can be formed by using a method and a material which are similar to those used in the step in FIG. 3B.

Subsequently, the step shown in FIG. 4B is performed. That is, the via hole 17 is filled with a conductive film to form the via 33 connecting to the interconnect 32, and the groove-like recess 17b is filled with the conductive film to form the seal via 43 connecting to the seal interconnect 42. The via 33 and the seal via 43 can be formed by using a method and a material which are similar to those used in the step in FIG. 3C.

Then, the step shown in FIG. 4C is performed. First, an interlayer insulating film 18 is formed on the interlayer insulating film 17. Then, in the interlayer insulating film 18, an interconnect groove 18a configured to form an interconnect 34 is formed on the via 33, and a seal interconnect groove 18b configured to form a seal interconnect 44 is formed on the seal via 43. The interconnect groove 18a and the seal interconnect groove 18b can be formed by using a method and a material which are similar to those used in the step in FIG. 3D.

Thereafter, the step shown in FIG. 4D is performed. That is, the interconnect groove 18a is filled with a conductive film to form the interconnect 34 connecting to the via 33, and the seal interconnect groove 18b is filled with the conductive film to form the seal interconnect 44 connecting to the seal via 43. The interconnect 34 and the seal interconnect 44 can be formed by using a method and a material which are similar to those used in the step in FIG. 3E.

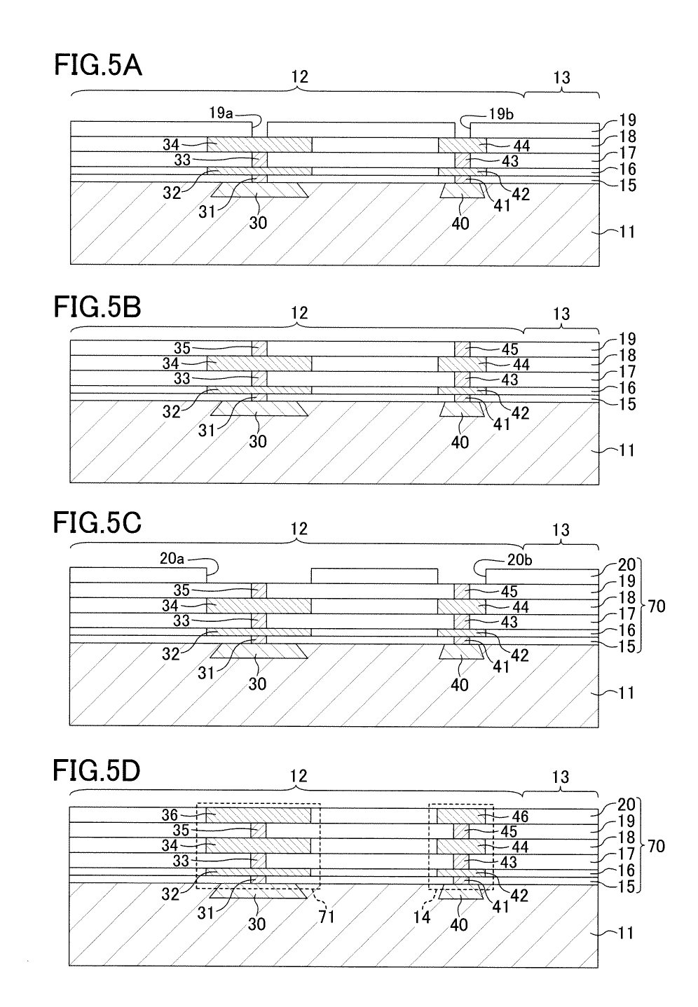

Then, the steps shown in FIGS. 5A-5D are performed. These steps are the steps of forming an interlayer insulating film 19 stacked over the interlayer insulating film 18, and a via 35 and a seal via 45 which are embedded in the interlayer insulating film 19, and of forming an interlayer insulating film 20 stacked on the interlayer insulating film 19, and an interconnect 36 and a seal interconnect 46 which are embedded in the interlayer insulating film 20.

As in the steps in FIGS. 4A-4D, the via 35 and the seal via 45, and the interconnect 36 and the seal interconnect 46 can be formed by forming the interlayer insulating film 19 having a via hole 19a and a groove-like recess 19b, and the interlayer insulating film 20 having an interconnect groove 20a and a seal interconnect groove 20b, and filling the via hole 19a and the groove-like recess 19b, and the interconnect groove 20a and the seal interconnect groove 20b with a conductive film, respectively.

Thus, an interconnect structure 71 is fowled which is formed by the interconnects 32, 34, and 36 and the vias 31, 33, and 35, and also a seal ring 14 is formed which is formed by the seal interconnects 42, 44, and 46 and the seal vias 41, 43, and 45.

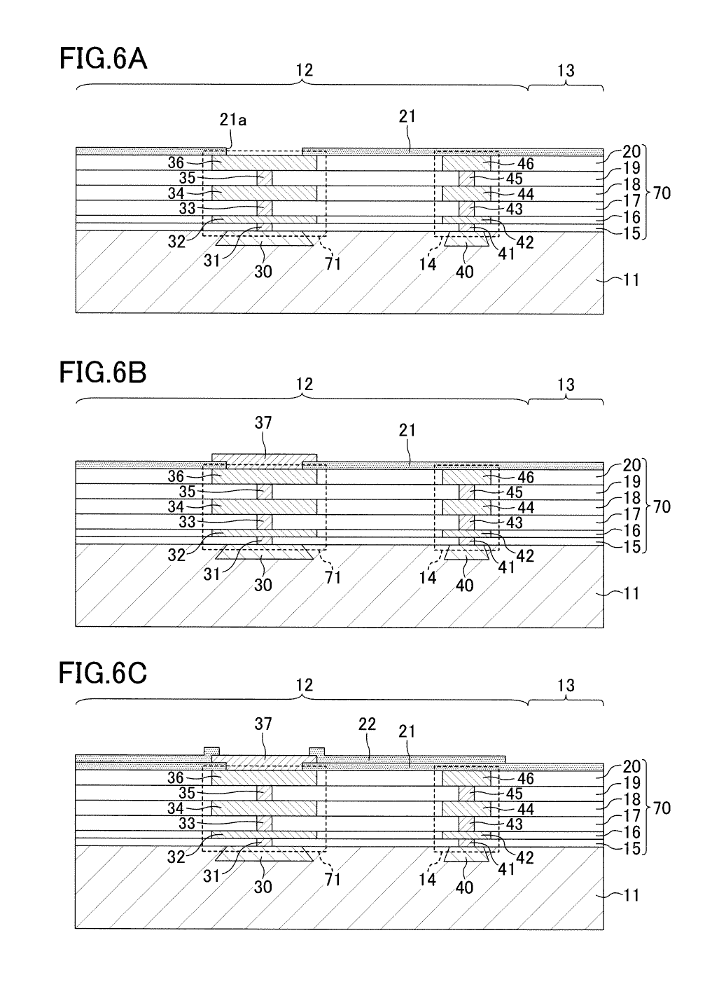

Then, the step shown in FIG. 6A is performed. First, a passivation film 21, which serves as a protective film for the interconnect 36, is deposited on the interconnect 36 as an uppermost interconnect layer and over the interlayer insulating film 20. Then, the passivation film 21 on the interconnect 36 is partially removed by a lithography method and a dry etching method to form an opening 21a.

Subsequently, as shown in FIG. 6B, a pad electrode 37 is formed in the opening 21a of the passivation film 21 so as to connect to the interconnect 36. Specifically, an aluminum (Al) film is deposited over the entire surface of the passivation film 21 including on the opening 21a by, e.g., a sputtering method. Then, the Al film is patterned over the interconnect 36a by using a lithography method and a dry etching method, thereby forming the pad electrode 37.

Thereafter, the step shown in FIG. 6C is performed. First, in the chip region 12, another passivation film 22 is deposited over the passivation film 21 including on the pad electrode 37. Then, an opening is formed in the passivation film 22 over the pad electrode 37 by a lithography method and a dry etching method, whereby a bonding pad is formed over the interconnect structure 71 by the pad electrode 37.

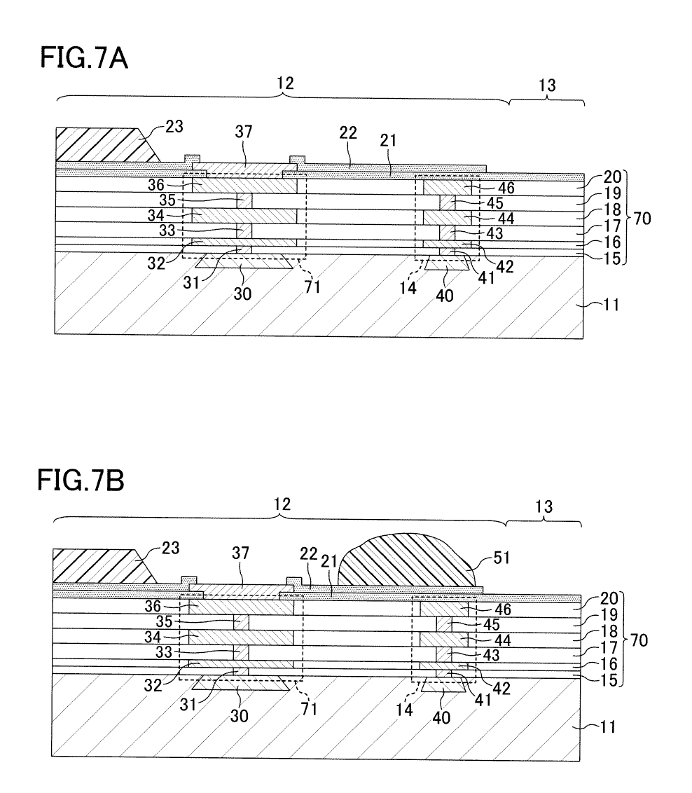

Then, as shown in FIG. 7A, a protective film 23 is formed in the chip region 12. Specifically, e.g., a liquid polyimide resin is applied by a spin coating method to the entire surface of the substrate 11 including on the pad electrode 37 and over the seal ring 14. Then, exposure and development are performed by a lithography method to remove a part of the liquid polyimide resin which is located on the pad electrode 37 and the vicinity thereof and over the seal ring 14 in the chip region 12, thereby forming the protective film 23 (see FIG. 1).

Then, as shown in FIG. 7B, a liquid epoxy resin is continuously applied to a region outside the pad electrode 37 in the chip region 12, including over the seal ring 14, by a dispensing method. The liquid epoxy resin is thermally cured to form on the peripheral edge of the chip region 12 a protruding portion 51 that continuously surrounds a region inside the chip region 12.

Then, the step of grinding the rear surface of the wafer and the dicing step are performed. Specifically, as shown in FIG. 8A, a protective tape 61 is first bonded to the entire surface on the main surface side (the side where the active layer 30, the protruding portion 51, etc. are formed) of the substrate 11. The protective tape 61 serves to protect the front surface of the wafer when grinding the rear surface thereof, and the protective tape 61 is pressed against the front surface of the wafer by a roller to allow the protective tape 61 to closely adhere to the front surface of the wafer. Since the protruding portion 51 is present, the protective tape 61 is allowed to closely adhere to the protruding portion 51 located in the peripheral edge of the chip. Thus, even if a gap is locally formed between the protective tape 61 and the front surface of the wafer due to the difference in height produced by the protective film 23, the protruding portion 51, etc., the scribe region 13 is completely separated from the chip region 12 by the adhesion portion between the protective tape 61 and the protruding portion 51.

Then, as shown in FIG. 8B, the substrate 11 is ground from its rear surface to a predetermined thickness. At this time, cutting water may enter the scribe region 13 located in the outer periphery of the wafer. However, since the scribe region 13 is separated from the chip region 12 by the protruding portion 51 as shown in FIG. 8A, the chip region 12 is not subjected to contamination with the cutting water. Thereafter, the protective tape 61 is removed.

Subsequently, as shown in FIG. 8C, the wafer is diced along the scribe region 13 into the chip regions 12 as individual chips, whereby a semiconductor device is obtained.

As described above, according to the manufacturing method of the semiconductor device of the present embodiment, the rear surface of the wafer is ground in the state where the protective tape 61 closely adheres to the protruding portion 51 that is provided in the peripheral edge of each chip region 12 so as to continuously surround the region inside the chip region 12. Thus, even if there is a gap between the protective tape 61 and the scribe region 13, and the cutting water enters the gap when grinding the rear surface of the wafer, the cutting water does not enter the chip region 12. Thus, although there is a difference in height between the chip region 12 and the scribe region 13 due to the protective film 23, this difference in height does not contribute to contamination of the chip region 12.

Moreover, no organic film such as polyimide is provided in the scribe region 13. The organic film in the scribe region 13 would cause disadvantages such as chippings during dicing. Thus, providing no organic film in the scribe region 13 can reduce generation of chippings, etc.

Note that although the protruding portion 51 is formed by a dispensing method using an epoxy resin in the above process, the present disclosure is not limited to this, and other resins and other methods may be used.

Although a planarizing method (a damascene method) is used to form the interconnects, the vias, the seal interconnects, and the seal vias, the present disclosure is not limited to this, and a stacking method involving no planarization may be used.

### Second Embodiment

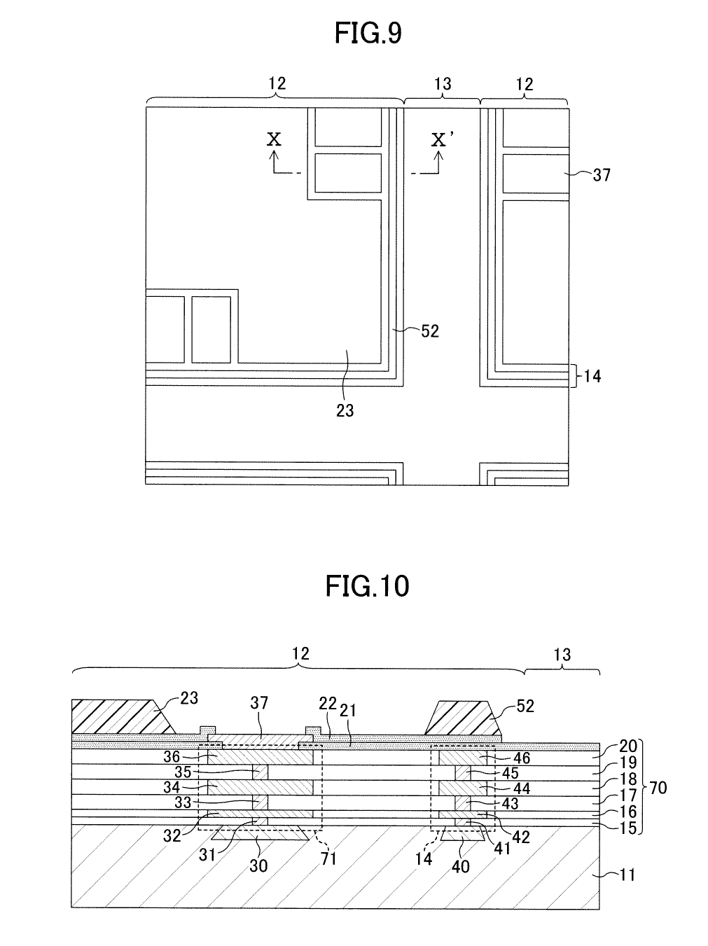

A second embodiment will be described below. FIG. 9 is a plan view showing an example semiconductor device of the present embodiment, and FIG. 10 is a diagram showing a cross-sectional structure taken along line X-X′ in FIG. 9. As in the first embodiment, these figures show a state where a plurality of chip regions 12 and a scribe region 13 configured to separate the chip regions 12 from each other by dicing are formed in a wafer.

The structure of the semiconductor device shown in FIGS. 9-10 will be described mainly with respect to the differences from the structure of the first embodiment shown in FIGS. 1-2. Note that the same components are denoted by the same reference characters.

In the present embodiment, as shown in FIGS. 9-10, a passivation film 22 is formed in the chip region 12 other than a region on the pad electrode 37. In order to protect the chip region 12, a protective film 23 is formed on the passivation film 22 so as to have an opening on the pad electrode 37, etc.

A protruding portion 52, which is made of the same material as the protective film 23, is formed over a seal ring 14 in the chip region 12 so as to continuously surround the inside of the chip region 12.

Processing of increasing surface roughness is performed on the respective surfaces of the protruding portion 52 and the protective film 23.

Even if such a protruding portion 52 is formed, the possibility can be reduced that the chip region 12 may be contaminated with cutting water when grinding the rear surface of the wafer, as in the first embodiment. Moreover, since the respective surfaces of the protruding portion 52 and the protective film 23 are subjected to the processing of increasing surface roughness, more satisfactory adhesion can be implemented between the protruding portion 52 and the protective film 23 and the protective tape that is bonded when grinding the rear surface of the wafer. Thus, the possibility can be more reliably reduced that the cutting water may enter the chip region 12.

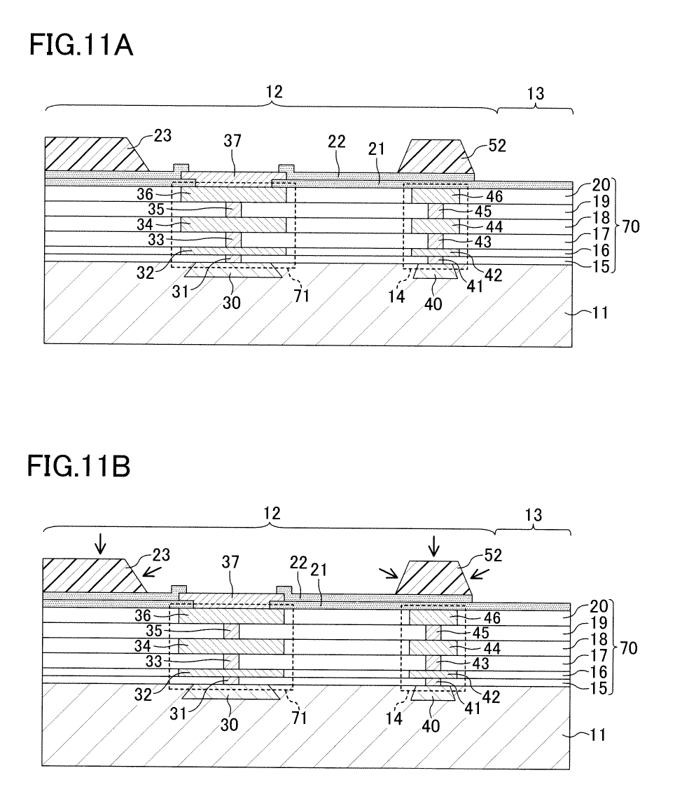

A manufacturing method for forming this structure will be described below. FIGS. 11A-11B are diagrams illustrating the steps of forming the structure having a cross section taken along line X-X′ in FIG. 9.

First, the structure of FIG. 6C is formed according to the steps of FIGS. 3A-6C described in the first embodiment. That is, an active layer 30 and a conductive layer 40, a stacked insulating film 70 formed by interlayer insulating films 15-20, an interconnect structure 71 and a seal ring 14 that are embedded in the stacked insulating film 70, a pad electrode 37, and a passivation film 22 are formed by using a substrate 11.

Then, the step shown in FIG. 11A is performed. First, e.g., a liquid polyimide resin is applied by a spin coating method to the entire surface of the substrate 11 including on the pad electrode 37. Then, exposure and development are performed by a lithography method to form both a protective film 23 having an opening in the vicinity of the pad electrode 37 in the chip region 12, and a protruding portion 52 over the seal ring 14. That is, the liquid polyimide resin is patterned by the lithography method, whereby the protective film 23 and the protruding portion 52 are simultaneously formed by using the same material.

Then, as shown in FIG. 11B, an ashing process is performed by using, e.g., oxygen plasma to roughen the respective surfaces of the protective film 23 and the protruding portion 52.

Thereafter, as described in FIGS. 8A-8C in the first embodiment, a protective tape is bonded, the rear surface of the wafer is ground, and then dicing is performed to divide the wafer into individual chips.

As described above, in the present embodiment as well, the protruding portion 52 is provided in the peripheral edge of each chip region 12 so as to continuously surround a region inside the chip region 12. This can reduce the possibility of contamination of the chip regions 12 when grinding the rear surface of the wafer.

Moreover, since the protruding portion 52 of the present embodiment is formed simultaneously with the protective film 23, the protruding portion 52 can be formed without increasing the number of steps. Since the respective surfaces of the protective film 23 and the protruding portion 52 are roughened, the protective tape is allowed to more reliably adhere to the protruding portion 52, thereby enhancing the effect of reducing the possibility of contamination.

An example of the roughening method is an ashing process using oxygen plasma. The ashing process is performed, e.g., at 1,000 W for 45 seconds.

### Third Embodiment

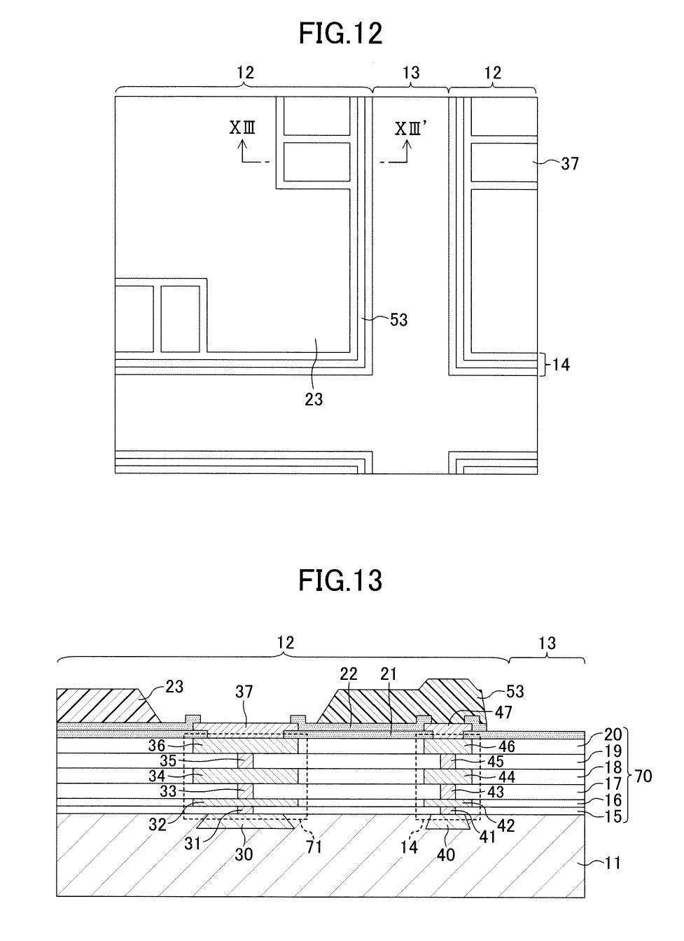

A third embodiment will be described below. FIG. 12 is a plan view showing an example semiconductor device of the present embodiment, and FIG. 13 is a diagram showing a cross-sectional structure taken along line XIII-XIII′ in FIG. 12. As in the first embodiment, these figures show a state where a plurality of chip regions 12 and a scribe region 13 configured to separate the chip regions 12 from each other by dicing are formed in a wafer.

The structure of the semiconductor device shown in FIGS. 12-13 will be described mainly with respect to the differences from the structure of the first embodiment shown in FIGS. 1-2. Note that the same components are denoted by the same reference characters.

In the present embodiment, as shown in FIG. 13, a passivation film 21 has an opening over the seal ring 14, in addition an opening over the interconnect structure 71. A cap layer 47 connecting to a seal interconnect 46 as an uppermost layer of the seal ring 14 is formed in the opening over the seal ring 14. Another passivation 22 formed on the passivation film 21 also has an opening on the cap layer 47.

A protruding portion 53, which is made of the same material as the protective film 23, is provided in a region of the chip region 12 located outside a pad electrode 37 and including a region on the cap layer 47, and the protruding portion 53 is higher than the protective film 23 by an amount corresponding to the cap layer 47. As in the first embodiment, this protruding portion 53 can also reduce the possibility of contamination of the chip region 12 with cutting water when grinding the rear surface of the wafer.

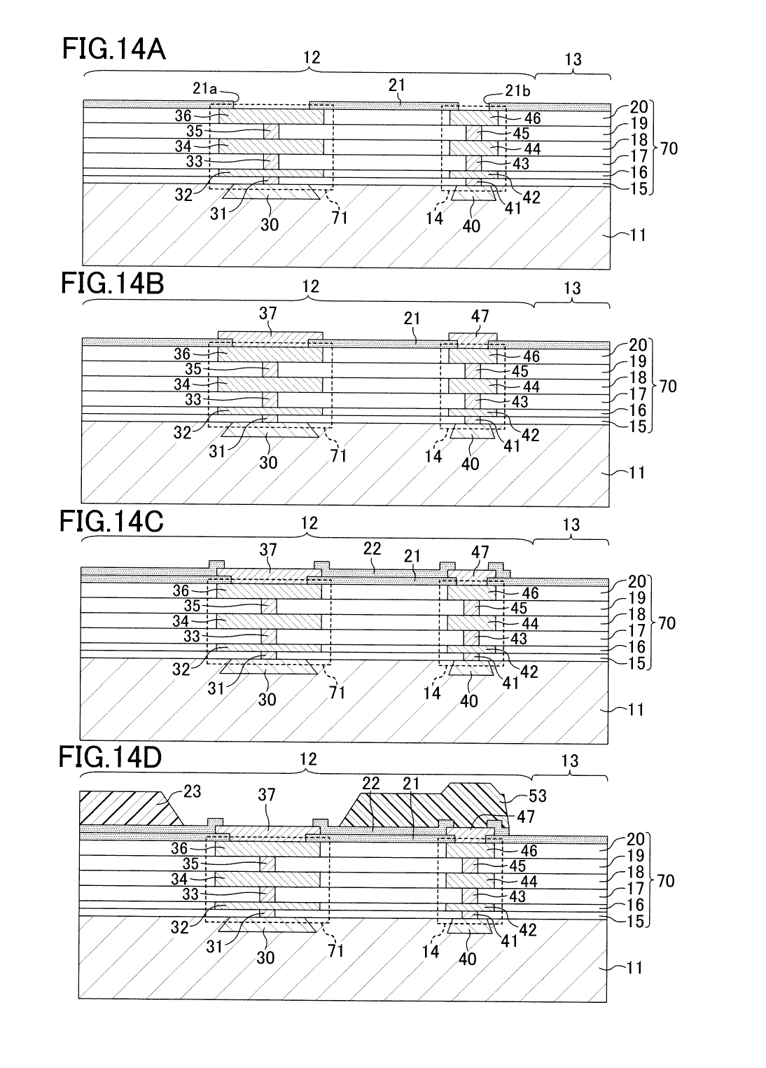

A manufacturing method for forming such a structure will be described below. FIGS. 14A-14D are diagrams illustrating the steps of forming the structure having a cross section taken along line XIII-XIII′ in FIG. 12.

First, the structure of FIG. 5D is formed according to the steps shown in FIGS. 3A-5D described in the first embodiment. An active layer 30 and a conductive layer 40, a stacked insulating film 70 formed by interlayer insulating films 15-20, and an interconnect structure 71 and a seal ring 14 that are embedded in the stacked insulating film 70 are formed by using a substrate 11.

Then, the step of FIG. 14A is performed. First, a passivation film 21 that serves as a protective film for an interconnect 36 is deposited over the interlayer insulating film 20, including on an interconnect 36 as an uppermost interconnect layer, and on a seal interconnect 46. Then, the passivation film 21 on the interconnect 36 and the seal interconnect 46 is removed by a lithography method and a dry etching method to form an opening 21a and an opening 21b.

Then, as shown in FIG. 14B, a pad electrode 37 connecting to the interconnect 36 is formed in the opening 21a of the passivation film 21, and a cap layer 47 connecting to the seal interconnect 46 is formed in the opening 21b. Specifically, an Al film is first deposited by, e.g., a sputtering method over the entire surface of the passivation film 21 including over the opening 21a and over the opening 21b. Then, the Al film is patterned over the interconnect 36 and the seal interconnect 46 by a lithography method and a dry etching method, thereby forming the pad electrode 37 and the cap layer 47, respectively.

Thereafter, the step in FIG. 14C is performed. First, another passivation film 22 is deposited on the passivation film 21 including on the pad electrode 37 and on the cap layer 47 in the chip region 12. Then, in the passivation film 22, openings are formed on the pad electrode 37 and the cap layer 47, respectively, by a lithography method and a dry etching method. Thus, a bonding pad is formed by the pad electrode 37 on the interconnect structure 71.

Then, the step in FIG. 14D is performed. First, e.g., a liquid polyimide resin is applied by a spin coating method to the entire surface of the substrate 11 including on the pad electrode 37 and on the cap layer 47. Then, exposure and development are performed by a lithography method to form both a protective film 23 having an opening in the vicinity of the pad electrode 37 in the chip region 12, and a protruding portion 53 on the seal ring 14. That is, the liquid polyimide resin is patterned by the lithography method, whereby the protective film 23 and the protruding portion 53 are simultaneously formed by using the same material.

Since the protruding portion 53 is formed on the cap layer 47, the protruding portion 53 is higher than the protective film 23 formed in a different region.

Then, as described in FIGS. 8A-8C of the first embodiment, a protective tape is bonded, the rear surface of the wafer is ground, and then dicing is performed to divide the wafer into individual chips.

As described above, in the present embodiment as well, the protruding portion 53 is provided in the peripheral edge of each chip region 12 so as to continuously surround the region inside the chip region 12. This can reduce the possibility of contamination of the chip regions 12 when grinding the rear surface of the wafer.

Moreover, since the protruding portion 53 of the present embodiment is formed simultaneously with the protective film 23, the protruding portion 53 can be formed without increasing the number of steps. Since the protruding portion 53 is formed on the cap layer 47, the protruding portion 53 is the highest portion on the substrate 11. This allows the protective tape to more reliably closely adhere to the protruding portion 52, thereby enhancing the effect of reducing the possibility of contamination.

Since the cap layer 47 is provided, the passivation films 21, 22 are divided into the side of the chip region 12 and the side of the scribe region 13 over the seal ring 14. Thus, even if the passivation films 21, 22 are delaminated due to impact, etc. during dicing shown in FIG. 8C, the delamination can be stopped over the seal ring 14. This is effective in increasing the manufacturing yield of the semiconductor device.

However, the effect of reducing the possibility of entrance of cutting water can also be produced by the presence of the protruding portion 53 over the seal ring 14. Thus, the respective openings and the cap layer 47 need not necessarily be provided in the passivation films 21, 22, and the protruding portion 52 may merely be formed simultaneously with the protective film 23.

Although a planarizing method (a so-called damascene method) is used to form the interconnects, the vias, the seal interconnects, and the seal vias, the present disclosure is not limited to this, and a stacking method involving no planarization may be used.

### Fourth Embodiment

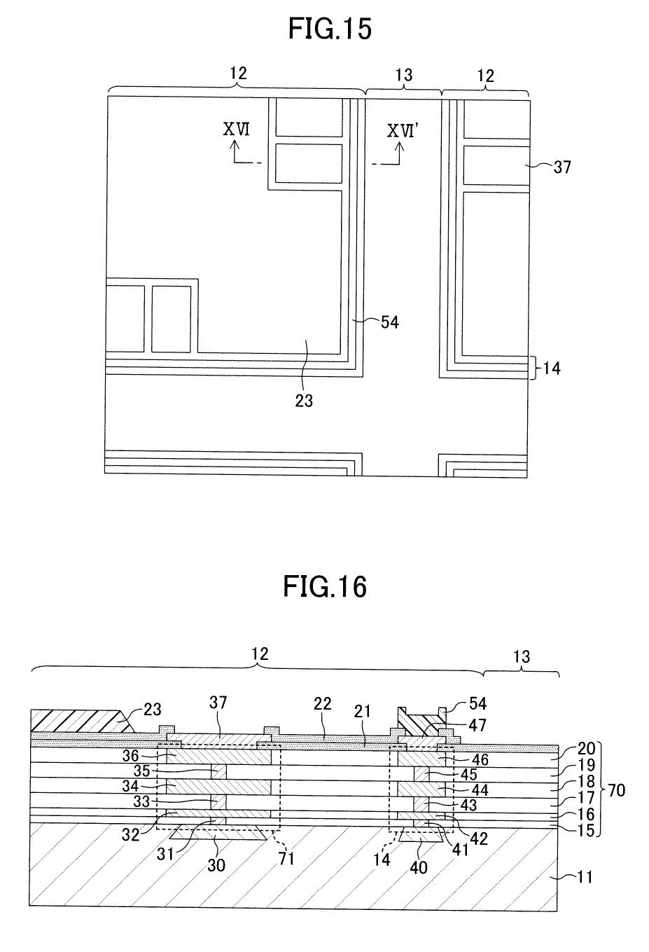

A fourth embodiment will be described below. FIG. 15 is a plan view showing an example embodiment of the present embodiment, and FIG. 16 is a diagram showing a cross-sectional structure taken along line XVI-XVI′ in FIG. 15. As in the first to third embodiments, these figures show a state in which a plurality of chip regions 12 and a scribe region 13 configured to separate the chip regions 12 from each other by dicing are formed in a wafer.

The structure of the present embodiment shown in FIGS. 15-16 will be described mainly with respect to the differences from the structure of the third embodiment shown in FIGS. 12-13. Note that the same components are denoted by the same reference characters.

In the present embodiment, a protruding portion 54 made of gold (Au) is provided on a cap layer 47. The present embodiment is different in this regard from the third embodiment (in which the protruding portion 53 made of the same material as the protective film 23 is provided). The present embodiment is the same as the third embodiment in that an opening is formed over the seal ring 14 in each of the passivation films 21, 22, and the cap layer 47 is provided therein.

Thus, the protruding portion 54 made of Au can also reduce the possibility of contamination of the chip regions 12 with cutting water when grinding the rear surface of the wafer.

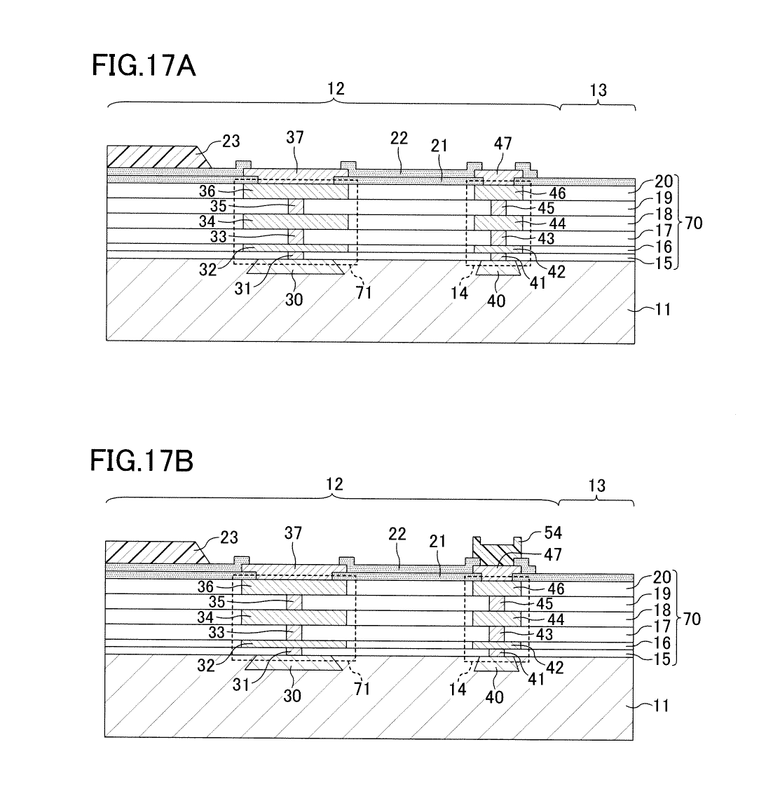

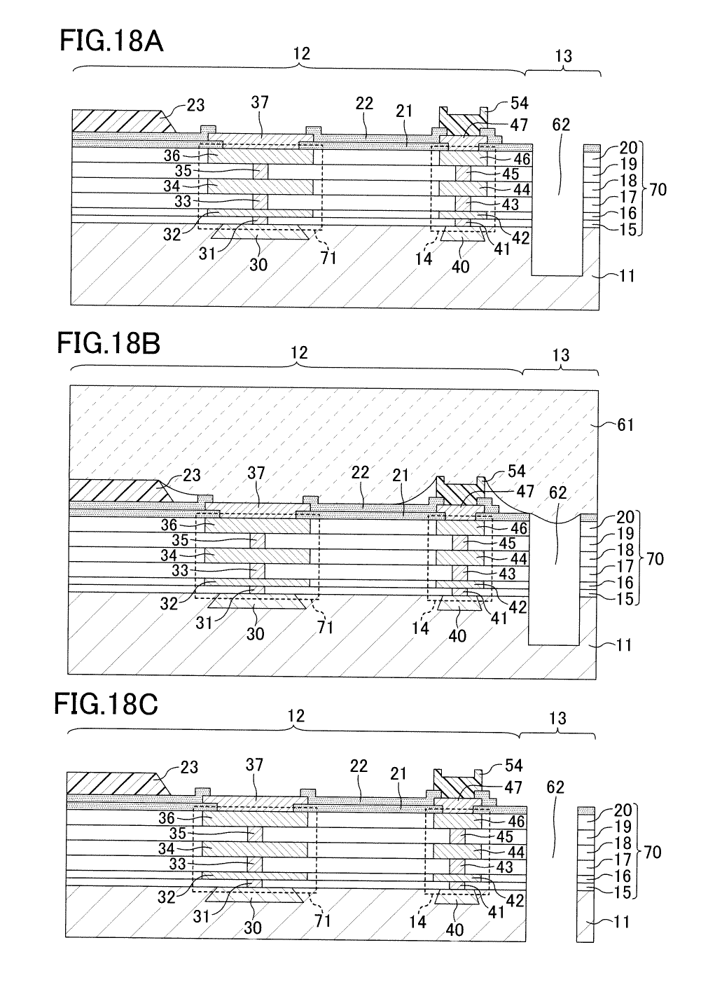

A manufacturing method for forming this structure will be described below. FIGS. 17A-17B are diagrams illustrating the steps of forming a cross-sectional structure taken along line XVI-XVI′ in FIG. 15, and FIGS. 18A-18C are diagrams illustrating grinding of the rear surface of the wafer and dicing.

First, the structure of FIG. 5D is formed according to the steps of FIGS. 3A-5D described in the first embodiment. That is, an active layer 30 and a conductive layer 40, a stacked insulating film 70 formed by interlayer insulating films 15-20, and an interconnect structure 71 and a seal ring 14 that are embedded in the stacked insulating film 70 are formed by using a substrate 11.

Then, the structure of FIG. 14C is formed according to the steps of FIGS. 14A-14C described in the third embodiment. That is, a passivation film 21 is provided over the interlayer insulating film 20, and a pad electrode 37 is formed in an opening on the interconnect structure 71, and a cap layer 47 is provided in an opening on the seal ring 14. Moreover, another passivation film 22 is formed on the passivation film 21, and openings are formed on the pad electrode 37 and the cap layer 47 in the passivation film 21, respectively.

Then, as shown in FIG. 17A, a protective film 23 is formed in the chip region 12. Specifically, e.g., a liquid polyimide resin is first applied by a spin coating method to the entire surface over the substrate 11 including on the pad electrode 37 and over the seal ring 14. Then, exposure and development are performed by a lithography method to remove a part of the liquid polyimide resin which is located in the vicinity of the pad electrode 37 and over the seal ring 14 in the chip region 12, thereby forming the protective film 23 (see FIG. 15).

Then, as shown in FIG. 17B, a protruding portion 54 made of Au is formed on the cap layer 47 by using an electroplating method. Instead of the protruding portion 54 made of Au, the protruding portion 54 may contain one of nickel (Ni), copper (Cu), tin (Sn), and aluminum (Al) as a main component. The protruding portion 54 need not necessarily be formed by the electroplating method, and other methods may be used as long as the protruding portion 54 can be selectively formed on the cap layer 54.

The chip regions 12 thus formed in the wafer are separated from each other as individual semiconductor devices, as shown in FIGS. 18A-18C. This is a method called a “dicing before grinding (DBG) method.”

First, as shown in FIG. 18A, the substrate 11 is cut along the scribe region 13 to an intermediate depth from the main surface side of the substrate 11, thereby forming a groove 62.

Next, as shown in FIG. 18B, a protective tape 61 is bonded to the main surface side of the substrate 11.

Then, as shown in FIG. 18C, grinding is performed from the rear surface of the substrate 11 so as to reach the groove 62. Thus, the chip regions 12 are separated from each other as individual semiconductor devices. Then, the protective tape 61 is removed, whereby individual chips are obtained.

As described above, in the semiconductor device and the manufacturing method of the present embodiment as well, the protruding portion 54 is provided in the peripheral edge of each chip region 12 so as to continuously surround a region inside the chip region 12. This can reduce the possibility of contamination of the chip region 12 when grinding the rear surface of the wafer. Note that this is also applicable when dicing is performed after grinding the rear surface of the wafer.

### Fifth Embodiment

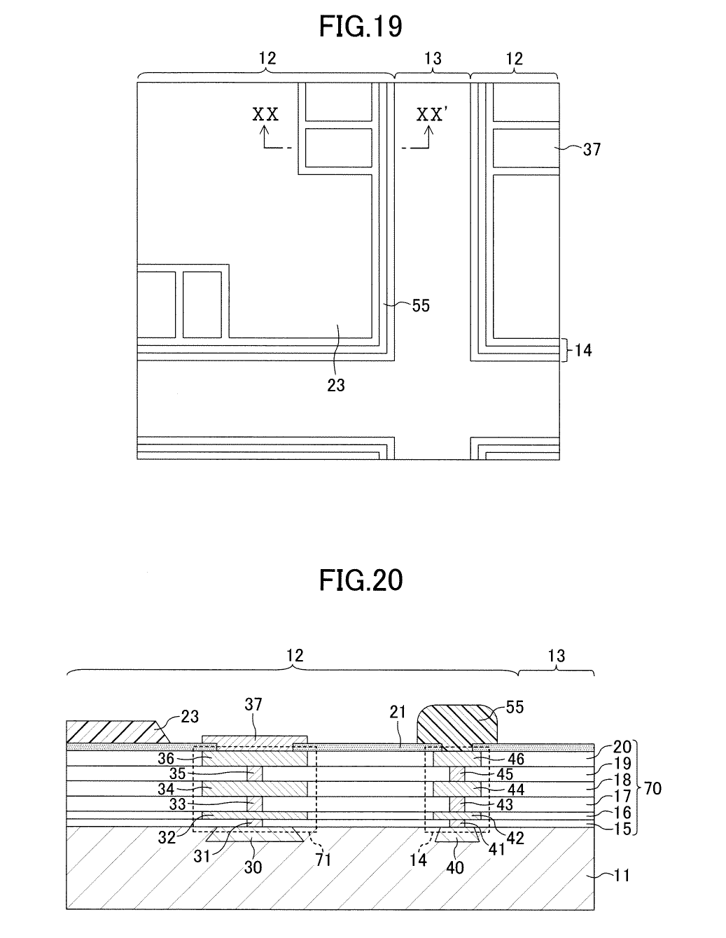

A fifth embodiment will be described below. FIG. 19 is a plan view showing an example semiconductor device of the present embodiment, and FIG. 20 is a diagram showing a cross-sectional structure taken along line XX-XX′ in FIG. 19. As in the first to fourth embodiments, these figures show a state where a plurality of chip regions 12 and a scribe region 13 configured to separate the chip regions 12 from each other by dicing are formed in a wafer.

The structure of the semiconductor device shown in FIGS. 19-20 will be described mainly with respect to the differences from the structure of the first embodiment shown in FIGS. 1-2. Note that the same components are denoted by the same reference characters.

In the present embodiment, an interconnect structure 71, and an interconnect 36 and a seal interconnect 46 as an uppermost layer of the seal ring 14 are made of Cu. Conductive films that form the remaining portion of the interconnect structure 71 and the seal ring 14 may be made of Cu, or may be made of other metals, etc.

Although the two passivation films 21, 22 are stacked together in the first embodiment, only one passivation film 21 is formed in the present embodiment. The passivation film 21 has an opening on the seal interconnect 46 as the uppermost layer of the seal ring 14, in addition to an opening on the interconnect 36 as an uppermost layer of the interconnect structure 71.

A protruding portion 55 made of nickel is formed in the opening on the seal interconnect 46 so as to connect to the seal interconnect 46.

In the chip region 12, the protective film 23 having an opening on the pad electrode 37 and the periphery thereof and over the seal ring 14 is provided on the passivation film 21.

The protruding portion 55 is provided in this configuration as well. This can reduce the possibility of contamination of the chip region 12 with cutting water when grinding the rear surface of the wafer.

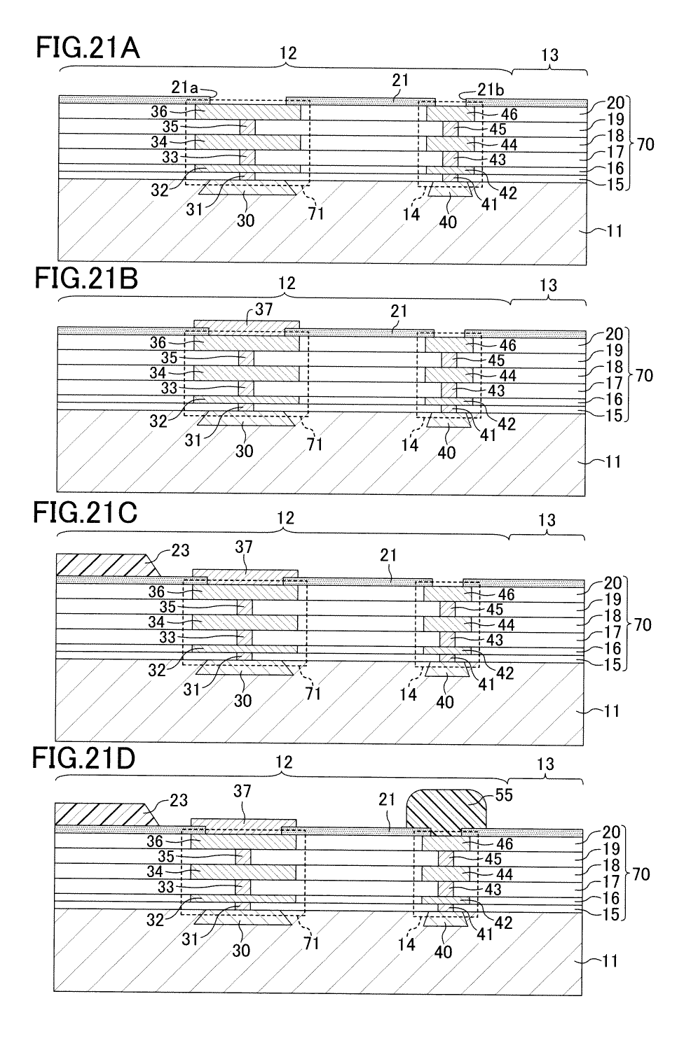

A manufacturing method for forming such a structure will be described below. FIGS. 21A-21D are diagrams illustrating the steps of forming a cross-sectional structure taken along line XX-XX′ in FIG. 19.

First, the structure of FIG. 5D is formed according to the steps of FIGS. 3A-5D described in the first embodiment. That is, an active layer 30 and a conductive layer 40, a stacked insulating film 70 formed by interlayer insulating films 15-20, and an interconnect structure 71 and a seal ring 14 that are embedded in the stacked insulating film 70 are formed by using a substrate 11. Cu is used as a conductive film that forms the interconnect 36 and the seal interconnect 46 of the uppermost layer.

Then, as shown in FIG. 21A, a passivation film 21 that serves as a protective film for the interconnect 36 is deposited on the interconnect 36 as an uppermost interconnect layer and the interlayer insulating film 20. Then, the passivation film 21 on the interconnect 36 and the seal interconnect 46, both made of Cu, is removed by a lithography method and a dry etching method, thereby sequentially forming an opening 21a and an opening 21b.

Then, as shown in FIG. 21B, a pad electrode 37 connecting to the interconnect 36 is formed in the opening 21a of the passivation film 21. Specifically, an Al film is first deposited by, e.g., a sputtering method over the entire surface of the passivation film 21 including over the opening 21a and over the opening 21b. Then, the Al film is patterned over the interconnect 36 by a lithography method and a dry etching method, thereby forming the pad electrode 37. Unlike the first and second embodiments, no cap layer 47 is formed at this time (no Al film is left on the seal interconnect 46).

Then, the step in FIG. 21C is performed. First, e.g., a liquid polyimide resin is applied by a spin coating method to the entire surface over the substrate 11 including on the pad electrode 37. Then, exposure and development are performed by a lithography method to form a protective film 23 having an opening in the vicinity of the pad electrode 37 and over the seal ring in the chip region 12.

Then, as shown in FIG. 21D, a protruding portion 55 is selectively formed by an electroless plating method only on the seal interconnect 46 made of Cu. Specifically, a process of applying a catalyst is performed to allow palladium (Pd) to be adsorbed onto the seal interconnect 46 made of Cu. Then, an activation process is performed, and the wafer is immersed in an electroless Ni plating solution, thereby selectively forming the protruding portion 54 on the Cu.

Then, as in the first embodiment, grinding of the rear surface of the wafer and dicing are performed to separate the chip regions from each other as individual chips, as shown in FIGS. 8A-8C.

According to the above manufacturing method, the protruding portion 55 can be selectively formed on the seal interconnect 46 without using a mask. This can reduce manufacturing cost.

### Sixth Embodiment

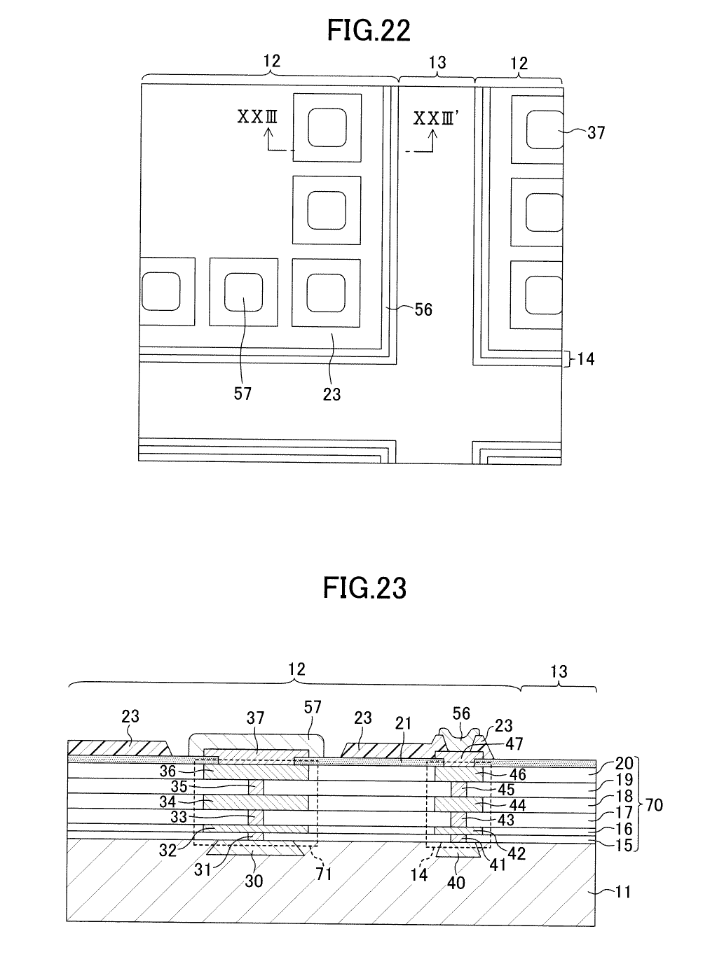

A sixth embodiment will be described below. FIG. 22 is a plan view showing an example semiconductor device of the present embodiment, and FIG. 23 is a diagram showing a cross-sectional structure taken along line XXII-XXII′ in FIG. 22. As in the first embodiment, these figures shows a state where a plurality of chip regions 12 and a scribe region 13 configured to separate the chip regions 12 from each other by dicing are formed in a wafer.

The structure of the semiconductor device shown in FIGS. 22-23 will be described below mainly with respect to the differences from the structure of the first embodiment shown in FIGS. 1-2. Note that the same components are denoted by the same reference characters.

Although the two passivation films 21, 22 are stacked together in the first embodiment, only one passivation film 21 is formed in the present embodiment. The passivation film 21 has an opening on a seal interconnect 46 as an uppermost layer of a seal ring 14, in addition to an opening on an interconnect 36 as an uppermost layer of an interconnect structure 71.

A pad electrode 37 connecting to the interconnect 36 and a cap layer 47 connecting to the seal interconnect 46 are formed in the openings of the passivation film 21, respectively.

A protective film 23 is formed on the passivation film 21 in the chip region 12.

In the first embodiment, as also shown in FIG. 1, the protective film 23 is formed to extend only to a position located on the side of the chip region 12 with respect to the seal ring 14. In the present embodiment, however, as shown in FIG. 22, the protective film 23 is formed so as to extend to a position near the boundary between the chip region 12 and the scribe region 13, and is also located on a portion between the pad electrode 37 and the cap layer 47, on the cap layer 47, etc. It should be noted that the protective film 23 has an opening on the pad electrode 37 and the periphery thereof, and on at least a part of the cap layer 47.

A protruding electrode 57 is provided on the pad electrode 37 that is exposed from the opening of the protective film 23. Moreover, a protruding portion 56 made of a metal is formed on the cap layer 47 so as to connect to a portion exposed from the opening of the protective film 23.

The protruding portion 56 is provided in such a configuration as well. This can reduce the possibility of contamination of the chip region 12 with cutting water when grinding the rear surface of the wafer. Moreover, since the protective film 23 is placed on the cap layer 47, and the protruding portion 56 is formed in the opening of the protective film 23, the protruding portion 56 is higher than the protruding electrode 57 and the protective film 23. This allows the protective tape 61 to more reliably closely adhere to the protruding portion 56 when grinding the rear surface of the wafer, thereby enhancing the effect of reducing the possibility of entrance of the cutting water.

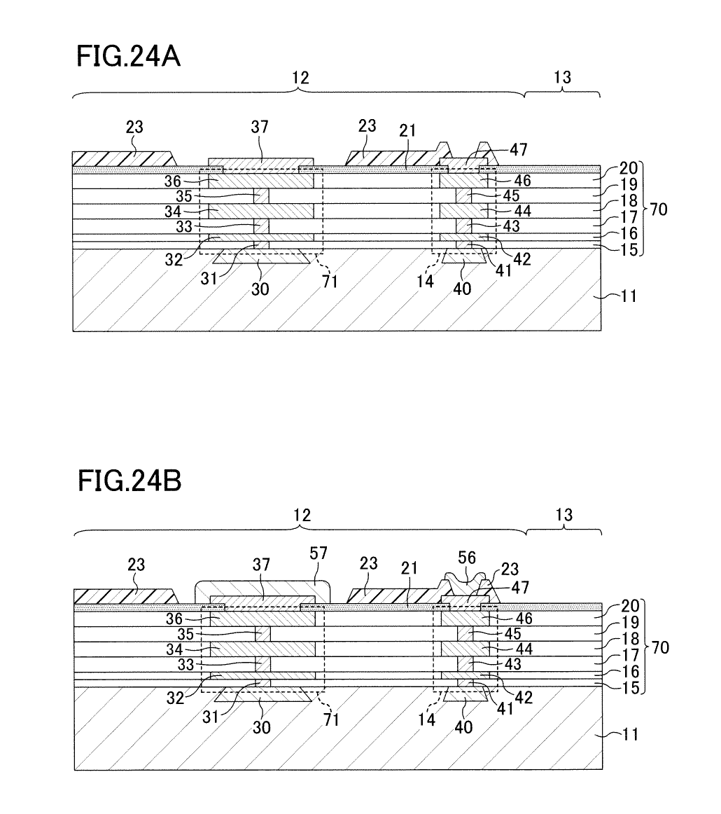

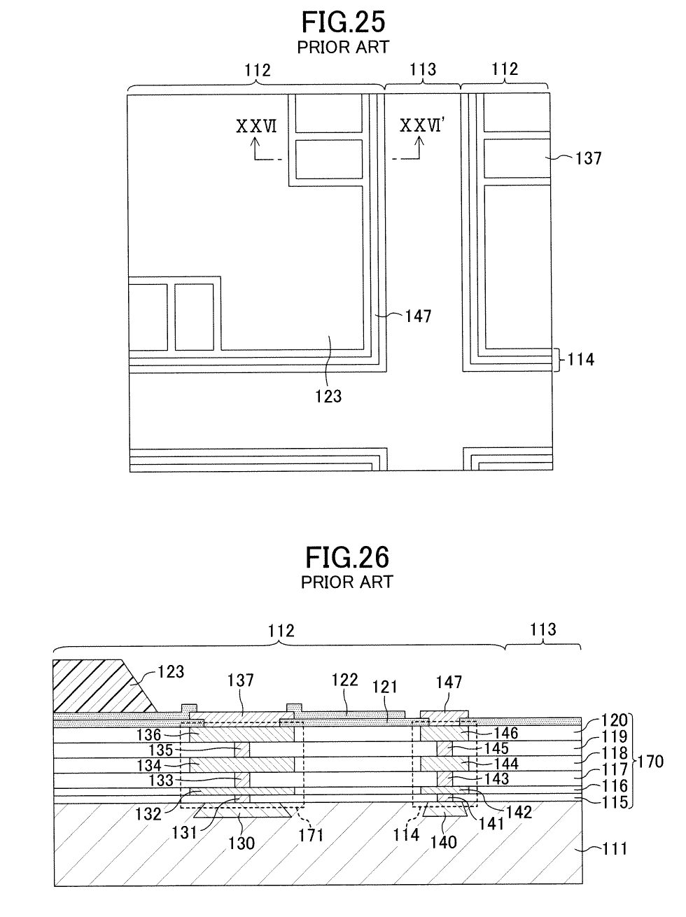

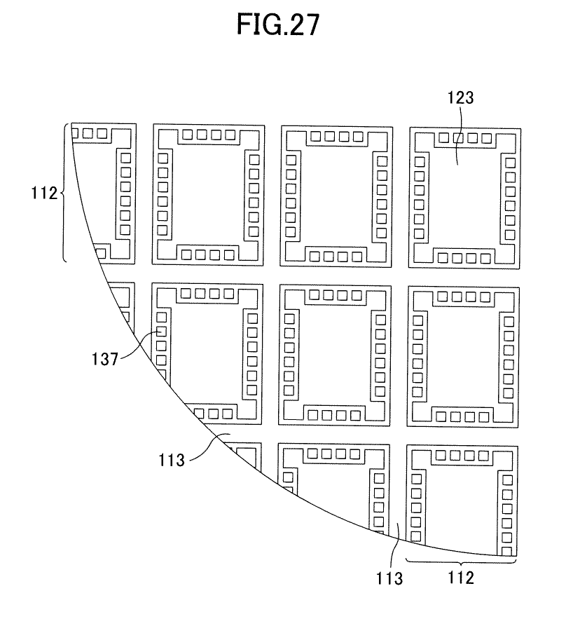

A manufacturing method for forming such a structure will be described below. FIGS. 24A-24B are diagrams showing the steps of forming a cross-sectional structure taken along line XXIII-XXIII′ in FIG. 22.

First, the structure of FIG. 5D is formed according to the steps of FIGS. 3A-5D described in the first embodiment. That is, an active layer 30 and a conductive film 40, a stacked insulating film 70 formed by interlayer insulating films 15-20, and an interconnect structure 71 and a seal ring 14 that are embedded in the stacked insulating film 70 are formed. It should be noted that Cu is used as a conductive film that forms the interconnect 36 and the seal interconnect 46 of an uppermost layer.

Next, a passivation film 21, a pad electrode 37, and a cap layer 47 are formed according to the steps of FIGS. 14A-14B described in the second embodiment.

Then, as shown in FIG. 24A, a protective film 23 is formed in the chip region 12. Specifically, e.g., a liquid polyimide resin is first applied by a spin coating method to the entire surface over a substrate 11 including on the pad electrode 37 and over the seal ring 14. Then, exposure and development are performed by a lithography method, thereby patterning the protective film 23 that extends to a position near the boundary between the chip region 12 and the scribe region 13 and has an opening on the pad electrode 37 and the periphery thereof and on at least a part of the cap layer 47.

Thereafter, as shown in FIG. 24B, a protruding electrode 57 is formed on the pad electrode 37, and a protruding portion 56 is formed on the cap layer 47 by an electroless plating method. Specifically, a zincate treatment is performed on the substrate 11 to cause displacement deposition of zinc (Zn) on the pad electrode 37 and the part of the cap layer 47 which is exposed from the opening of the protective film 23. Then, the wafer is immersed in an electroless Ni plating solution to grow Ni, and then the wafer is further immersed in an electroless Au plating solution to grow an Au film. Thus, the protruding electrode 57 and the protruding portion 56 are formed as Ni having the Au film thereon.

Thereafter, as in the first embodiment, grinding of the rear surface of the wafer and dicing are performed as shown in FIGS. 8A-8C, thereby separating the chip reigns 102 from each other as individual chips.

According to the manufacturing method of the present embodiment described above, the protruding portion 56 can be formed on the cap layer 47 simultaneously with forming the protruding electrode 57 on the pad electrode 37 by an electroless plating method. Thus, the protruding portion 56 can be formed without increasing the number of steps. Moreover, the protective film 23 configured to protect the chip region 12 is formed so as to cover a part of the cap layer 47, and the protective film 23 is used to increase the height of the protruding portion 56. This can also be implemented without increasing the number of steps.

Thus, the semiconductor device having the protruding portion 56 in the peripheral edge of the chip region 12 can be manufactured while suppressing an increase in the number of steps.

Although the technique of the present disclosure is described above with respect to the six specific examples, the present disclosure is not limited to them, and various modifications can be made without departing from the spirit and scope of the present disclosure.

For example, in the example described above, an organic protective film made of polyimide is formed as the protective film 23 in the chip region 12. However, the technique of the present disclosure is also applicable when no organic protective film is provided.

Although the DBG method is described in the fourth embodiment, the DBG method may be used in other embodiments. Moreover, a method in which dicing is performed after grinding the rear surface of the wafer may be used in the fourth embodiment.

As described above, according to the semiconductor device and the manufacturing method of the present disclosure, a protruding portion is provided so as to continuously surround a region inside the chip region. Providing such a protruding portion can reduce the possibility of contamination of the chip region with cutting water when grinding the rear surface of the wafer, and can also address the need to reduce the thickness of semiconductor devices. Thus, the semiconductor device and the manufacturing method of the present disclosure are useful as a thinner semiconductor device and a manufacturing method thereof.

What is claimed is:

1. A semiconductor device, comprising:
an electrode pad formed in a chip region on a substrate; and
a protruding portion continuously formed on a region outside the electrode pad within the chip region so as to surround a region inside the chip region, wherein
the protruding portion is higher than the electrode pad.

2. The semiconductor device of claim 1, wherein
the chip region includes
an element formed in the substrate,
an interlayer insulating film formed on the substrate, and
an interconnect structure formed in the interlayer insulating film and connected to the element, and
the electrode pad is connected to the element via the interconnect structure.

3. The semiconductor device of claim 2, further comprising:
a seal ring continuously formed in the interlayer insulating film so as to surround the element and the interconnect structure, wherein
the protruding portion is formed at least over the seal ring.

4. The semiconductor device of claim 3, wherein
a cap layer is provided on the seal ring, and
the protruding portion is formed at least over the seal ring with the cap layer interposed therebetween.

5. The semiconductor device of claim 2, further comprising:
a protective film made of an organic film and formed on the interlayer insulating film in a region inside the protruding portion.

6. The semiconductor device of claim 5, wherein
the protruding portion has a height equal to or greater than that of the protective film.

7. The semiconductor device of claim 1, wherein
at least an upper surface of the protruding portion is a rough surface portion.

8. The semiconductor device of claim 1, wherein
the protruding portion is made of an organic film.

9. The semiconductor device of claim 8, wherein
the organic film is formed by applying a liquid resin to an entire surface over the substrate and patterning the liquid resin.

10. The semiconductor device of claim 3, wherein
the protruding portion is a protruding portion made of a metal and connected to the seal ring.

11. The semiconductor device of claim 10, further comprising:
a protruding electrode formed on the electrode pad.

12. The semiconductor device of claim 11, wherein
the protruding portion made of the metal is higher than the protruding electrode.

13. The semiconductor device of claim 10, wherein
the protruding portion made of the metal contains one of Ni, Au, Cu, Sn, and Al as a main component.
